(19) United States
(12) Patent Application Publication
(10) Pub. No.: US 2011/0073992 A1
(43) Pub. Date: Mar. 31, 2011

(54) MANUFACTURING METHOD OF SEMICONDUCTOR DEVICE AND SEMICONDUCTOR DEVICE

(75) Inventors: Masahiro WADA, Kanagawa (JP); Takaaki NAGAI, Kanagawa (JP)

(73) Assignee: RENESAS ELECTRONICS CORPORATION, Kanagawa (JP)

(21) Appl. No.: 12/893,312

(22) Filed: Sep. 29, 2010

(30) Foreign Application Priority Data
Sep. 29, 2009 (JP) 2009-223966

(51) Int. Cl. H01L 27/108; H01L 21/76

(52) U.S. Cl. 257/532; 438/386; 257/E27.084; 257/E21.585

(57) ABSTRACT

A first interlayer dielectric is formed over a substrate, and an electric conductor pillar is formed in the first interlayer dielectric. A damascene wiring part insulating film is formed over an upper surface of the first interlayer dielectric. The damascene wiring part insulating film above the electric conductor pillar is removed to form an opening part for capacitance, and an insulating film for capacitive element is formed over the upper surface of the first interlayer dielectric. The insulating film for capacitive element and the first interlayer dielectric above the electric conductor pillar are removed to form a trench for wiring. Metal bodies are embedded in the opening part for capacitance and the trench for wiring. The metal body in the opening part for capacitance is to be an upper electrode of the capacitive element, and the metal body in the trench for wiring is to be a logic wiring.

### INCORPORATION BY REFERENCE

This application is based upon and claims the benefit of priority from Japanese patent application No. 2009-223966, filed on Sep. 29, 2009, the disclosure of which is incorporated herein in its entirety by reference.

### BACKGROUND

1. Field of the Invention

The present invention relates to a manufacturing method of a semiconductor device and the semiconductor device.

In particular, the present invention relates to a manufacturing method of a semiconductor device embedded with a logic circuit and a metal capacitive element.

2. Description of Related Art

LSI embedded with a logic circuit and a capacitive element is well known such as a DRAM embedded LSI. In recent years, as more improvement in the function is required along with higher integration of the semiconductor device, a method is desired which adds a metal capacitive element by a simple method without influencing the operation of the logic circuit.

Japanese Unexamined Patent Application Publication No. H04-99372 discloses a manufacturing method of a semiconductor device aiming for increase in the capacity of DRAM.

The manufacturing method of the semiconductor device disclosed in Japanese Unexamined Patent Application Publication No. H04-99372 is illustrated in FIGS. 23A to 23I.

In the technique disclosed in Japanese Unexamined Patent Application Publication No. H04-99372, as illustrated in FIG. 23D, electric conductors 5 and 5a of poly-Si are embedded in contact holes opened in a diffusion layer 1a.

The electric conductor 5 will be a lower electrode of a capacitor.

Further, the electric conductor 5a will be a bit line contact part connected to an upper aluminum wiring layer.

Next, an insulating film (SiO₂) 6 is formed over the surface of the electric conductors 5 and 5a by thermal oxidation (FIG. 23F).

This insulating film 6 becomes a dielectric of the capacitor.

The insulating film over the upper part of the electric conductor 5a to be the bit line contact part is removed by photolithography and etching.

Poly-Si to be a capacitor electrode is grown over the entire surface by CVD to form an electric conductor layer 7, which is to be an upper electrode of the capacitor (FIG. 23G).

An insulating layer 8 made of PSG (phospho-silicate-glass) is formed over the entire surface, and a window for contacting a bit line is opened above the electric conductor 5 (FIG. 23H).

An aluminum wiring layer 9 is grown by PVD over the insulating layer 8 as wiring material for a bit line, and a protective layer 10 is formed over the aluminum wiring layer 9 (FIG. 23I).

In this way, the bit line contact via the electric conductor 5a is formed at the same time as the capacitor composed of the lower electrode 5, the dielectric layer 6, and the upper electrode 7 is formed.

This method can expand the area of the capacitor electrode using the upper and side surfaces of the electric conductor 5, which is pillar-shaped, and attempt to increase the capacitance of the capacitor.

### SUMMARY

Although the bit line contact via the electric conductor 5a is formed, in the method disclosed in Japanese Unexamined Patent Application Publication No. H04-99372, the insulating film 6 and the electric conductor layer 7 remain on the side surface of the electric conductor 5a, which is to be the bit line contact part.

If the insulating film 6 and the electric conductor layer 7 remain on the side surface of the electric conductor 5a as described above, the insulating film 6 and the electric conductor layer 7 will be parasitic capacitance elements.

Such parasitic capacitance influences the logic operation including bit lines, and there is a problem that the device characteristics are deteriorated.

Further, in the method disclosed in Japanese Unexamined Patent Application Publication No. H04-99372, after forming the electric conductors 5 and 5a, the insulating film 6 and the upper electrode 7 are removed each time by lithography and the bit line contact is formed above the electric conductor 5.

Therefore, the present inventor has found a problem that three or more lithography processes must be added to embed the logic circuit and the capacitor, and a large increase is required in the number of process.

An exemplary aspect of the present invention is a manufacturing method of a semiconductor device embedded with a logic unit and a metal capacitive element that includes forming a first interlayer dielectric over a substrate, forming a plurality of electric conductor pillars in the first interlayer dielectric, making some of the plurality of electric conductor pillars to be lower electrodes of the metal capacitive element, and some of the remaining plurality of electric conductor pillars to be contact plugs of the logic unit, smoothing an upper surface of the first interlayer dielectric, and then forming a damascene wiring part insulating film over the upper surface of the first interlayer dielectric, removing the damascene wiring part insulating film above the lower electrode to form an opening part for capacitance, forming an insulating film for capacitive element over the upper surface of the first interlayer dielectric, removing the insulating film for capacitive element and the first interlayer dielectric above the contact plug to form a trench for wiring, embedding metal bodies in the opening part for capacitance and the trench for wiring, and making the metal body in the opening part for capacitance to be an upper electrode of the capacitive element and the metal body in the trench for wiring to be a logic wiring. Another exemplary aspect of the present invention is a manufacturing method of a semiconductor device embedded with a logic unit and a metal capacitive element that includes forming a first interlayer dielectric over a substrate, forming a plurality of electric conductor pillars in the first interlayer dielectric, making some of the plurality of electric conductor pillars to be lower electrodes of the metal capacitive element, and some of the remaining plurality of electric conductor pillars to be contact plugs of the logic unit, smoothing an upper surface of the first interlayer dielectric, and then forming a damascene wiring part insulating film over the upper surface of the first interlayer dielectric, removing the damascene wiring part insulating film above the contact plug and the lower electrode to form a trench for wiring and an opening part for capacitance, forming an insulating film for capacitive element over the damascene wiring part insulating film, removing the insulating film for capacitive element above the contact plug, embedding metal bodies in the opening part for capacitance and the trench for wiring, and making the metal body in the opening part for capacitance to be an upper electrode of the capacitive element and the metal body in the trench for wiring to be a logic wiring.

In the present invention, since the components (the contact plug and the wiring) of the logic unit and the components (the lower electrode and the upper electrode) of the metal capacitive element are simultaneously formed of the same material, it is possible to reduce the increase in the number of processes to embed the logic unit and the metal capacitive element to the minimum. According to the present invention, as the insulating film for capacitive element does not remain near or on the side surface of the contact plug (the electric conductor pillar), unnecessary parasitic capacitance is not generated in the logic unit. Therefore, accurate logic operation can be realized while embedding the logic unit and the metal capacitive element.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 illustrates a manufacturing method of a semiconductor device according to a first exemplary embodiment;

FIG. 2 illustrates the manufacturing method of the semiconductor device according to the first exemplary embodiment;

FIG. 3 illustrates the manufacturing method of the semiconductor device according to the first exemplary embodiment;

FIG. 4 illustrates the manufacturing method of the semiconductor device according to the first exemplary embodiment;

FIG. 5 illustrates the manufacturing method of the semiconductor device according to the first exemplary embodiment;

FIG. 6 illustrates the manufacturing method of the semiconductor device according to the first exemplary embodiment;

FIG. 7 illustrates the manufacturing method of the semiconductor device according to the first exemplary embodiment;

FIG. 8 illustrates a second exemplary embodiment;

FIG. 9 illustrates a manufacturing process according to the second exemplary embodiment;

FIG. 10 illustrates a third exemplary embodiment;

FIG. 11 illustrates a modification 1;

FIG. 12 is a cross-sectional diagram taken along the line XII-XII of FIG. 11;

FIG. 13 illustrates an example of an electrode size of a common parallel plate capacitor for contrast;

FIG. 14 illustrates a modification 2;

FIG. 15 illustrates a modification 3;

FIG. 16 is a cross-sectional diagram taken along the line XVI-XVI line of FIG. 15;

FIG. 17 illustrates a manufacturing method of the semiconductor device according to a fourth exemplary embodiment;

FIG. 18 illustrates the manufacturing method of the semiconductor device according to the fourth exemplary embodiment;

FIG. 19 illustrates the manufacturing method of the semiconductor device according to the fourth exemplary embodiment;

FIG. 20 illustrates the manufacturing method of the semiconductor device according to the fourth exemplary embodiment;

FIG. 21 illustrates the case when a capacitive element insulating film remains on the side surface of a trench for wiring according to the fourth exemplary embodiment;

FIG. 22 illustrates the case when the capacitive element insulating film remains on the side surface of the trench for wiring according to the fourth exemplary embodiment;

FIG. 23A illustrates a semiconductor manufacturing method according to a related art;

FIG. 23B illustrates the semiconductor manufacturing method according to the related art;

FIG. 23C illustrates the semiconductor manufacturing method according to the related art;

FIG. 23D illustrates the semiconductor manufacturing method according to the related art;

FIG. 23E illustrates the semiconductor manufacturing method according to the related art;

FIG. 23F illustrates the semiconductor manufacturing method according to the related art;

FIG. 23G illustrates the semiconductor manufacturing method according to the related art;

FIG. 23H illustrates the semiconductor manufacturing method according to the related art; and

FIG. 23I illustrates the semiconductor manufacturing method according to the related art.

### DETAILED DESCRIPTION OF THE EXEMPLARY EMBODIMENTS

Hereinafter, exemplary embodiments of the present invention are described with reference to the drawings.

### First Exemplary Embodiment

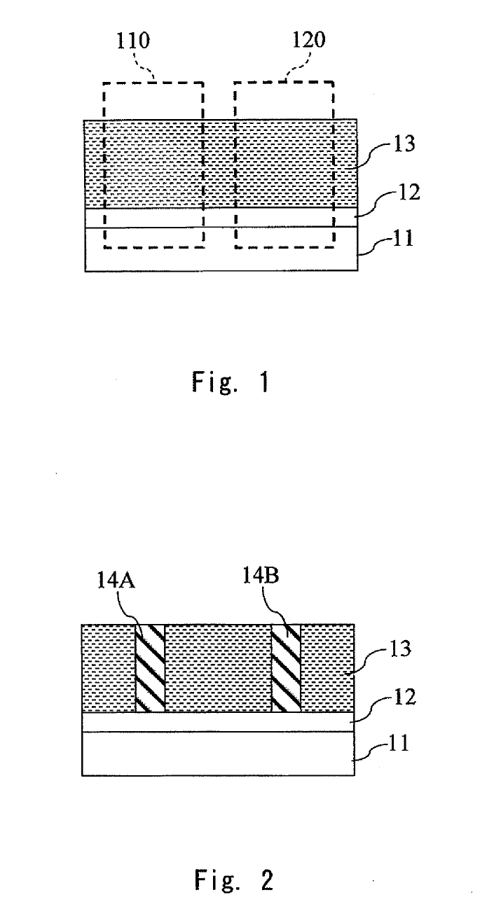

FIGS. 1 to 7 illustrate a manufacturing method of a semiconductor device according to a first exemplary embodiment.

The semiconductor device is embedded with a logic unit and a metal capacitance element.

Each manufacturing process is explained with reference to the drawings.

In FIG. 1, a diffusion layer 12 is formed over a substrate 11, and a first interlayer dielectric 13 is formed over the diffusion layer 12.

Although not especially explained in detail here, various circuit elements such as a transistor and a resistor are formed in the diffusion layer 12 according to the circuit design.

For example, the diffusion layer 12 is divided by shallow trench isolation (STI) for forming a transistor, and a source/drain diffusion layer is formed inside each of the surrounded isolation region.

Then, a gate electrode is formed over the substrate 11 with an insulating film interposed therebetween, to form a transistor.

Alternatively, various resistors are formed over the diffusion layer 12.

In the following explanation, a case is described in which a logic unit is formed in the part indicated by numeral 110, and a metal capacitive element is formed in the part indicated by numeral 120 in FIG. 1.

Next, as illustrated in FIG. 2, electric conductor pillars 14A and 14B are formed in the first interlayer dielectric 13.

The electric conductor pillars 14A and 14B have the same configuration.

The electric conductor pillars 14A and 14B may be formed by general contact hole opening and embedding processes.

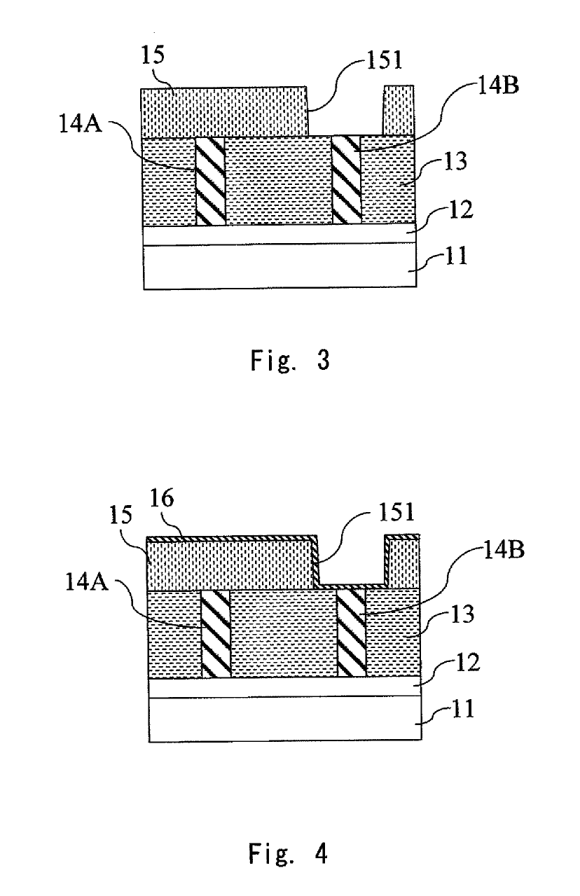

After forming the electric conductor pillars 14A and 14B, smoothing is performed. Next, a damascene wiring part insulating film 15 is grown over the first interlayer dielectric 13. Then, as illustrated in FIG. 3, the upper part of the electric conductor pillar 14B is opened to form an opening part for capacitance 151.

Next, as illustrated in FIG. 4, a capacitive element insulating film 16 is grown over the damascene wiring part insulating film 15.

Note that the damascene wiring part insulating film 15 and the capacitive element insulating film 16 may be formed of the same material (for example SiO₂).

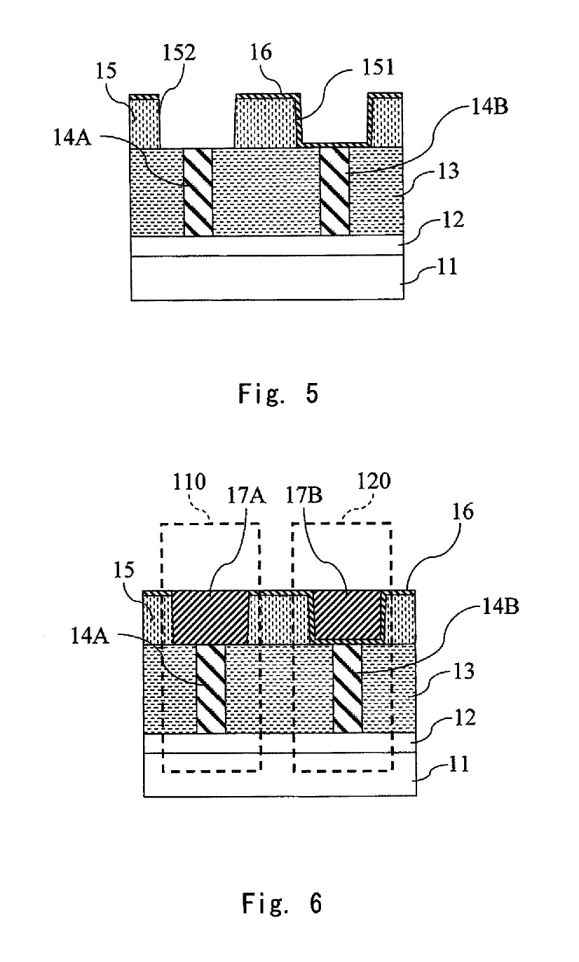

Next, as illustrated in FIG. 5, the damascene wiring part insulating film 15 and the capacitive element insulating film 16 above the electric conductor pillar 14A are etched to open above the electric conductor pillar 14A.

Then a trench for wiring 152 is formed.

In this state, the capacitive element insulating film 16 is formed immediately above the electric conductor pillar 14B, whereas no insulating film remains on the bottom or side surfaces of the trench for wiring 152, which is immediately above the electric conductor pillar 14A.

It is needless to say that the insulating film or electric conductor unit do not exist which generates parasitic capacitance on the side surface of the electric conductor pillar 14A.

Next, as illustrated in FIG. 6, metal bodies 17A and 17B are embedded in the opening part for capacitance 151 and the trench for wiring 152 by a general wiring embedding method.

As preferable material for the metal bodies 17A and 17B, there are W and Cu, for example.

On the other hand, material with high resistance such as poly-Si and Ti is not preferable.

After that, the upper surface is smoothed.

The metal capacitive element 120 is formed by a combination of the electric conductor pillar 14B, the capacitive element insulating film 16, and the metal body 17B. Accordingly, the electric conductor pillar 14B will be a lower electrode of the metal capacitive element, and the metal body 17B will be an upper electrode thereof. Further, the electric conductor pillar 14A will be a contact plug, and the metal body 17A will be a wiring.

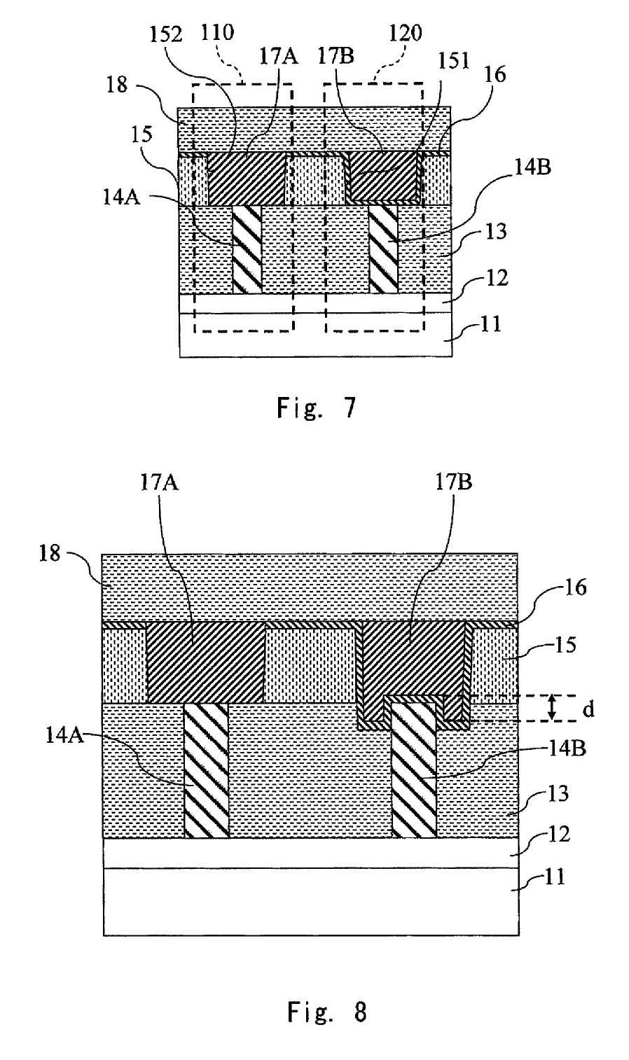

Subsequently, as illustrated in FIG. 7, an upper layer insulation film 18 is formed, and if necessary, a wiring layer is sequentially formed.

The semiconductor device embedded with the logic unit 110 and the metal capacitive element 120 is formed as described above.

The first exemplary embodiment can produce the following exemplary advantages.

(1) When embedding the logic unit 110 and the metal capacitive element 120, the contact plug of the logic unit 110 and the lower electrode of the metal capacitive element 120 are formed of the same material at the same time as the electric conductor pillars 14A and 14B.

Moreover, the wiring of the logic unit 110 and the upper electrode of the capacitive element 120 are formed of the same material at the same time as the metal bodies 17A and 17B.

As the components (the contact plug and the wiring) of the logic unit and the components (the lower electrode and the upper electrode) of the metal capacitive element are formed of the same material at the same time, the increase in the number of process to embed the logic unit 110 and the metal capacitive element 120 can be extremely reduced.

In other words, in this exemplary embodiment, only the process to dispose the opening part for capacitive element 151 above the electric conductor pillar 14B is added to the process to form a normal logic circuit, as illustrated in FIG. 3.

Thus, according to this embodiment, the semiconductor device embedded with the logic unit and the metal capacitive element can be manufactured by the addition of extremely small number of process.

(2) According to this exemplary embodiment, since the capacitive element insulating film 16 does not remain near or on the side surface of the contact plug (the electric conductor pillar 14A), unnecessary parasitic capacitance is not generated in the logic unit 110. Therefore, accurate logic operation can be realized while embedding the logic unit 110 and metal capacitive element 120.
(3) In this exemplary embodiment, since the components (the contact plug and the wiring) of the logic unit and the components (the lower electrode and the upper electrode) of the metal capacitive element are formed in a similar manner at the same time, it is necessary to select the material which can achieve both functions as logic unit and the metal capacitive element.

The material with too high resistance is not appropriate for logic wiring in view of this point, thus W or Cu is used and not poly-Si or Ti.

Therefore, the semiconductor device embedded with the logic unit 110 and the metal capacitive element 120 is efficiently manufactured while no inconvenience arises such as deterioration in operation characteristics of the logic circuit.

### Second Exemplary Embodiment

Next, a second exemplary embodiment of the present invention is described.

The basic configuration of the second exemplary embodiment is the same as that of the first exemplary embodiment, however the second exemplary embodiment is characterized in that the upper electrode of the metal capacitive element is opposed also at the side surface of the electric conductor pillar, which is the lower electrode, and the opposing area of the electrode is larger than the first exemplary embodiment.

To be specific, as illustrated in FIG. 8, the bottom surface of the metal body 17B, which is to be the upper electrode, is lower except the part immediately above the electric conductor pillar 14B, which is the lower electrode.

It only needs to change a part of the manufacturing process of the first exemplary embodiment to be the manufacturing process of the second exemplary embodiment.

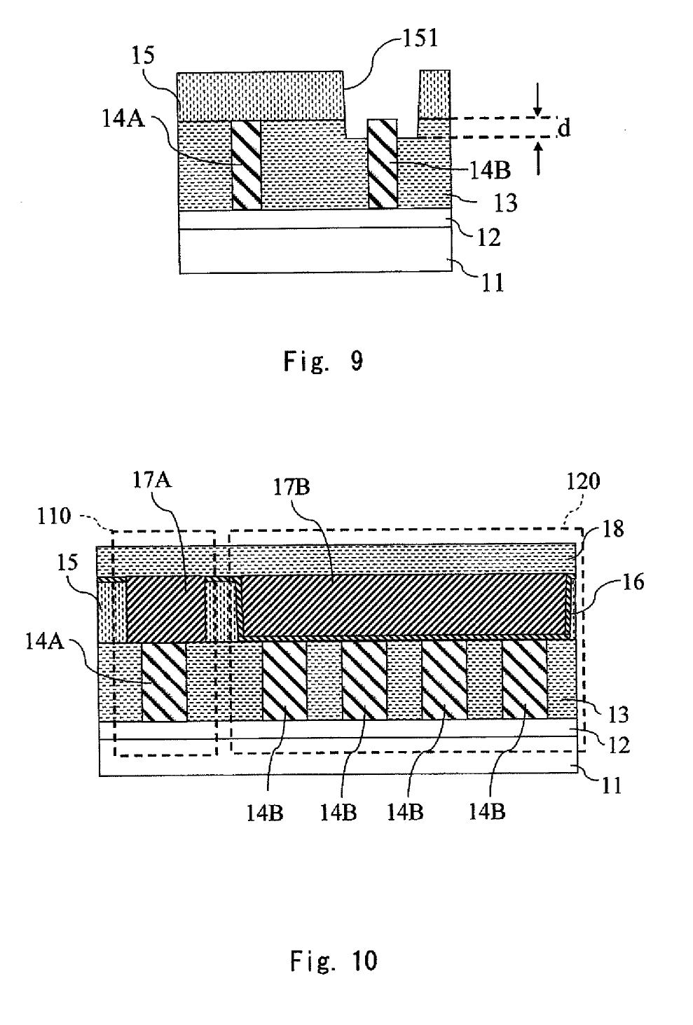

Specifically, as illustrated in FIG. 9, when forming the opening part for capacitance 151, an etching should be performed down to a depth d below the upper surface position of the electric conductor pillars 14A and 14B.

Note that when stopping the etching for the opening part for capacitance 151 at the position of the depth d below the upper surface position of the electric conductor pillars 14A and 14B, the etching depth may be controlled by time or a stopper film may be formed at a predetermined position of the first interlayer dielectric 13.

With such configuration, the metal body 17B (the upper electrode) and the electric conductor pillar 14B (the lower electrode) are opposed also at the side surface of the electric conductor pillar 14B.

Accordingly, the opposing area of the metal body 17B (the upper electrode) and the electric conductor pillar 14B (the lower electrode) increases, and thereby increasing the capacitance of the capacitor by the corresponding amount.

Thus, the occupation area is same as the first exemplary embodiment, however the capacitance can be larger than the first exemplary embodiment.

### Third Exemplary Embodiment

The basic configuration of a third exemplary embodiment is the same as that of the first exemplary embodiment, however the third exemplary embodiment is characterized in that the lower electrode of the metal capacitive element is composed of a plurality of electric conductor pillars.

As illustrated in FIG. 10, the metal capacitive element 120 includes a plurality of the electric conductor pillars 14B (four pillars in FIG. 10).

The metal body 17B as the upper electrode has the length to oppose the plurality of electric conductor pillars 14B.

Then the capacitance of the metal capacitive element 120 can be increased.

[Modification 1]

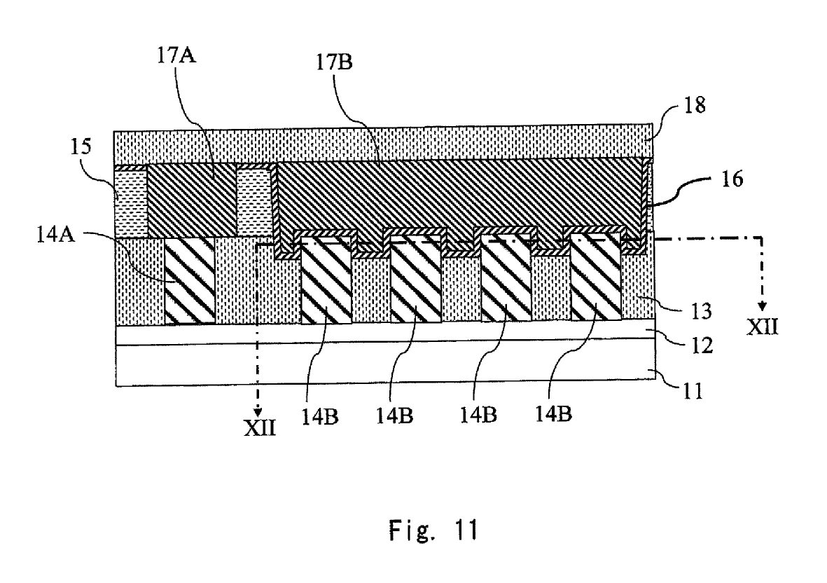

FIG. 11 illustrates a modification 1.

In the modification 1, as shown in the third exemplary embodiment, a plurality of lower electrodes (the electric conductor pillar 14B) of the metal capacitive element are disposed, and as shown in the second exemplary embodiment, the upper electrode of the metal capacitive element is opposed also at the side surface of the electric conductor pillar, which is the lower electrode.

By such configuration, the capacitance of the metal capacitive element can be further increased.

The capacitance of the modification 1 is contrasted with the capacitance of a common parallel plate capacitor.

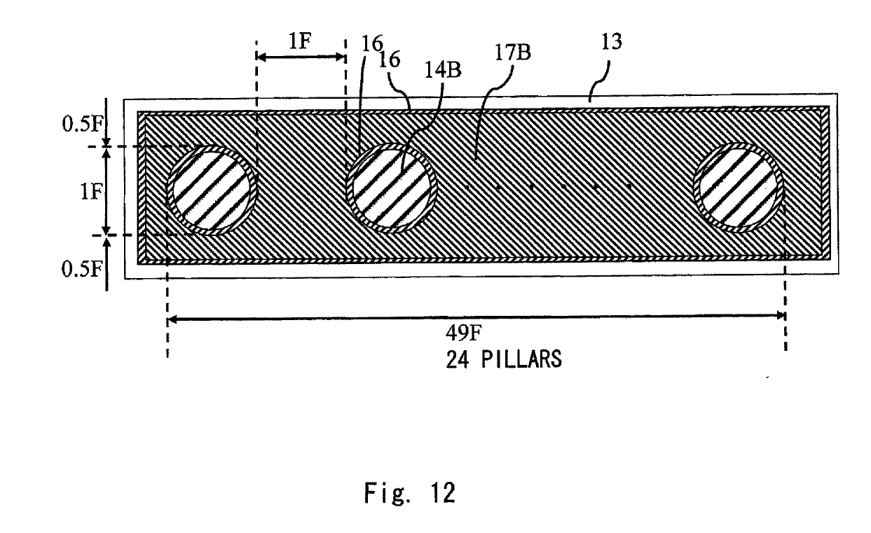

FIG. 12 is a cross-sectional diagram taken along the line XII-XII of FIG. 11.

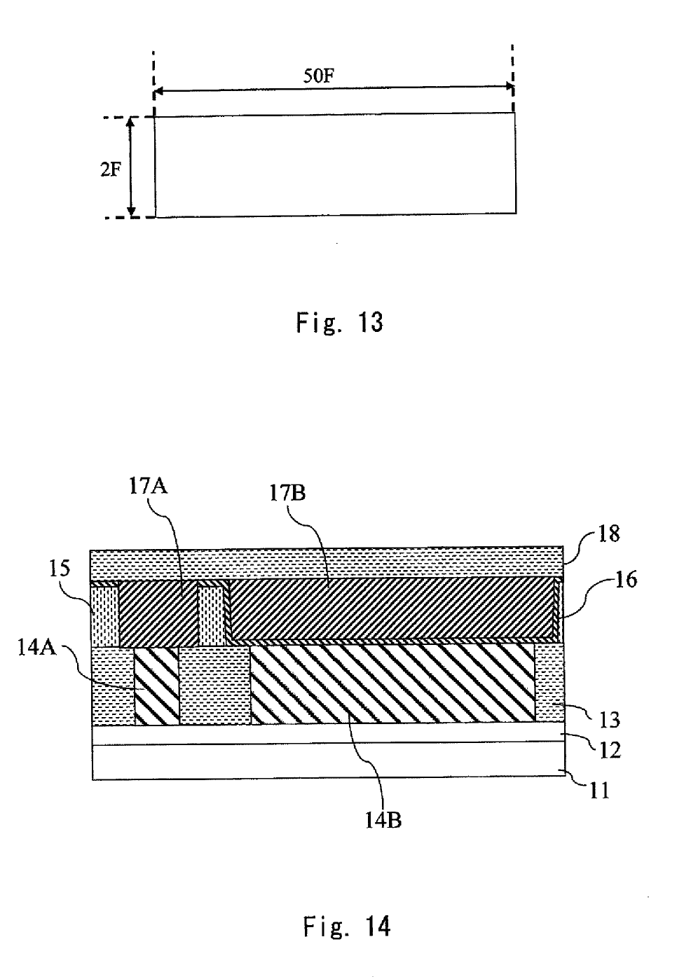

Further, FIG. 13 illustrates an electrode of the common parallel plate capacitor for contrast.

In FIGS. 12 and 13, “F” indicates a design unit of the size.

The size of the electrode of the common parallel plate capacitor illustrated in FIG. 13 shall be length 2 F and width 50 F.

At this time, the capacitance area is 2 F×50 F=100 F².

On the other hand, in the example illustrated in FIG. 12, it will be as follows.

A ditch depth d shall be 2 F in this example.

$$\begin{matrix}( Capacitance area ) = \{ ( vertical plane ) + ( side surface ) \} \times 24 \\ = \{ {π ( 0.5 F )}^{2} + π F \times 2 F \} \times 24 \\ = 169.6 {F}^{2}\end{matrix}$$

Thus, by providing the ditch amount d in this way, it is possible to increase the capacitance area with the same occupation area as compared to the common parallel plate capacitor of the related art.

In this example, the capacitance area can be about 1.7 times that of the common parallel plate capacitor.

(Modification 2)

FIG. 14 illustrates a modification 2.

In the modification 2, one electric conductor pillar 14B is formed to be long.

The metal body 17B, which is the upper electrode, is formed to be long to match the electric conductor pillar 14B.

Even by such configuration, the opposing area of the upper electrode and the lower electrode increases, and thereby increasing the capacitance.

[Modification 3]

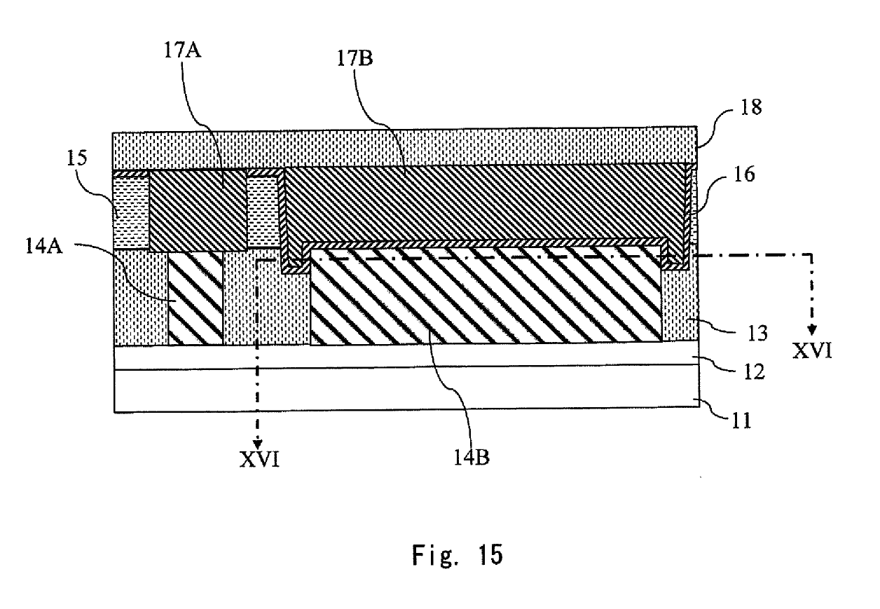

FIG. 15 illustrates a modification 3.

In the modification 3, the electric conductor pillar 14B is formed to be long as shown in the modification 2, and the upper electrode 17B of the metal capacitive element is opposed also at the side surface of the electric conductor pillar 14B, which is the lower electrode as shown in the second exemplary embodiment.

The capacitance of the modification 3 is contrasted with the capacitance of the common parallel plate capacitor.

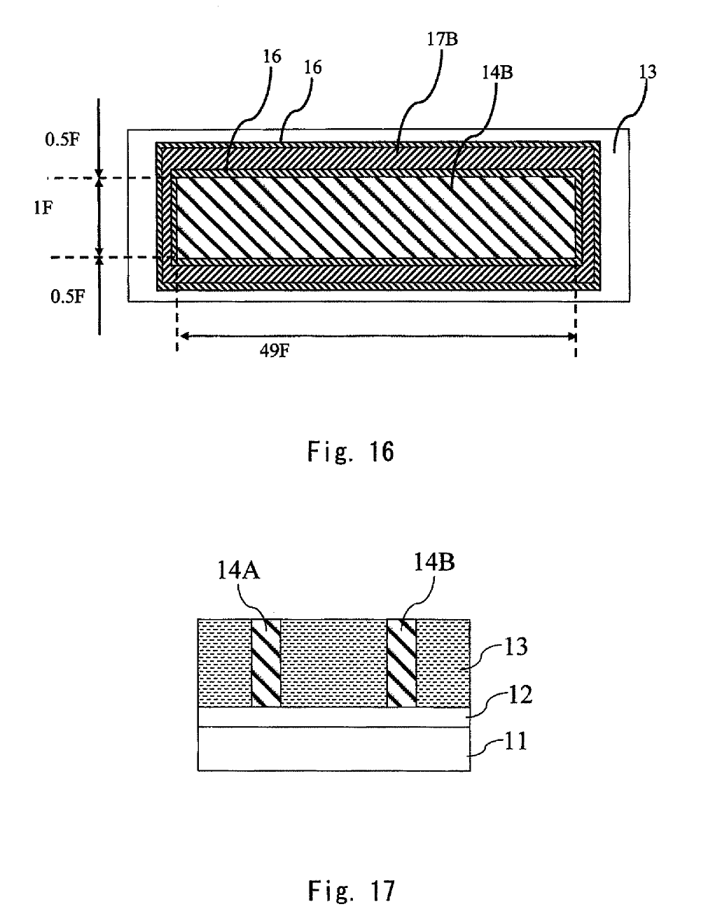

FIG. 16 is a cross-sectional diagram taken along the line XVI-XVI of FIG. 15.

In FIG. 16, “F” indicates a design unit of the size.

The size of the electrode of the common parallel plate capacitor shall be length 2 F and width 50 F (FIG. 13).

At this time, the capacitance area is 2 F×50 F=100 F².

On the other hand, in the example illustrated in FIGS. 15 and 16, it will be as follows.

In this example, the ditch depth d shall be 2 F.

$$\begin{matrix}Capacitance area = vertical plane + \{ ( side surface 1 ) + ( side surface 2 ) \} \times 2 \\ = 1 F \times 49 F + \{ ( 49 F \times 2 F ) + ( 1 F \times 2 F ) \} \times 2 \\ = 249 {F}^{2}\end{matrix}$$

Thus, by providing the ditch amount d in this way, it is possible to double or more the capacitance area with the same occupation area as compared to the common parallel plate capacitor according to the related art.

### Fourth Exemplary Embodiment

A fourth exemplary embodiment is described hereinafter.

The basic configuration of the fourth embodiment is same as the first exemplary embodiment, however the fourth exemplary embodiment is characterized in that the trench for wiring 152 and the opening part for capacitance 151 in the logic unit and the metal capacitive element unit are formed at the same time.

FIGS. 17 to 20 illustrate a manufacturing method of a semiconductor device according to the fourth exemplary embodiment.

In FIG. 17, the electric conductor pillars 14A and 14B are formed in the first interlayer dielectric 13 in a similar way as the first exemplary embodiment of FIG. 2.

Next, the damascene wiring part insulating film 15 is grown over the first interlayer dielectric 13.

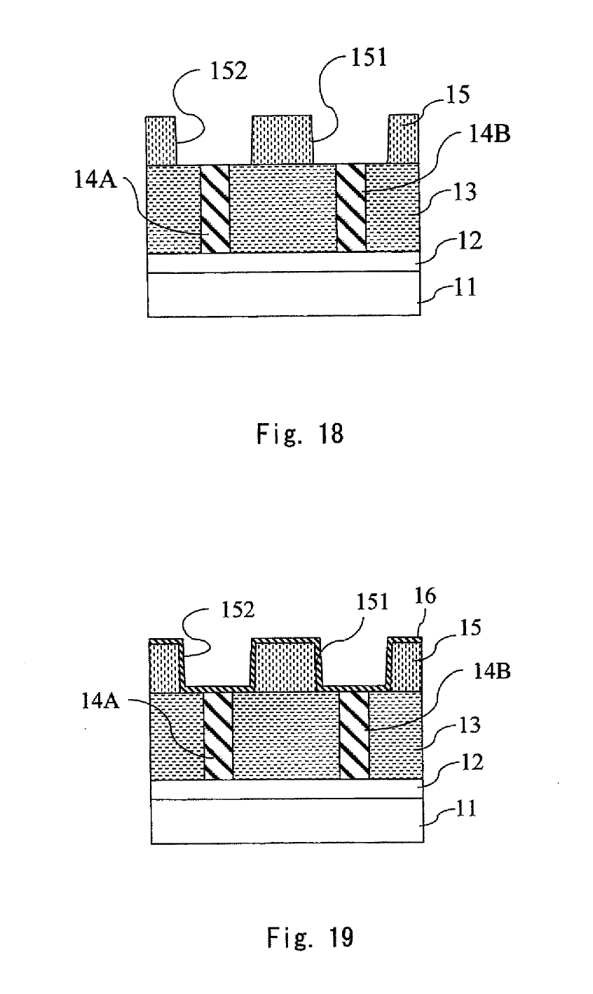

Then, as illustrated in FIG. 18, the upper part of the electric conductor pillars 14A and 14B are opened by lithography.

At this time, the opening above the electric conductor pillar 14A will be the trench for wiring 152, and the opening above the electric conductor pillar 14B will be the opening for capacitance 151.

Next, the capacitive element insulating film 16 is formed over the damascene wiring part insulating film 15 (FIG. 19).

In the fourth exemplary embodiment, the materials for the damascene wiring part insulating film 15 and the capacitive element insulating film 16 should be the ones in which selectivity can be obtained by etching.

Then, the capacitive element insulating film 16 positioned in the logic unit is removed by lithography (FIG. 20).

The subsequent processes are the same as FIGS. 6 and 7 of the first exemplary embodiment.

Since an unnecessary insulating film does not remain in the logic unit even with such configuration, parasitic capacitance is not generated.

In the fourth exemplary embodiment, as the trench for wiring 152 and the opening for capacitance 151 are formed by etching at the same time, it is possible to reduce the time required for etching and the entire manufacturing time as compared to the first exemplary embodiment.

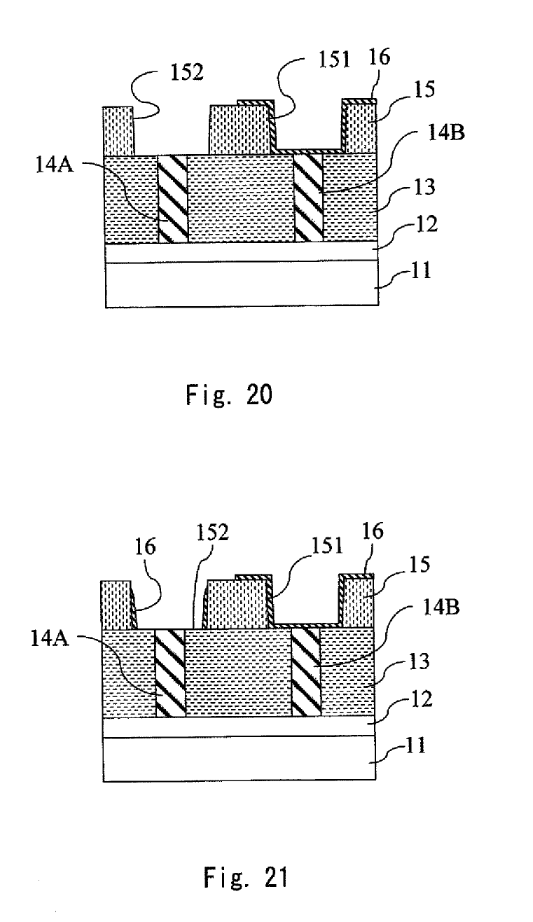

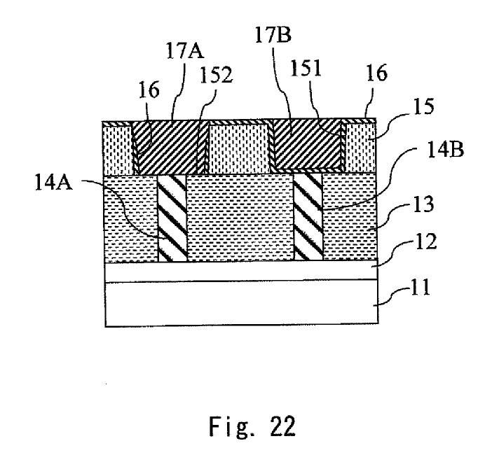

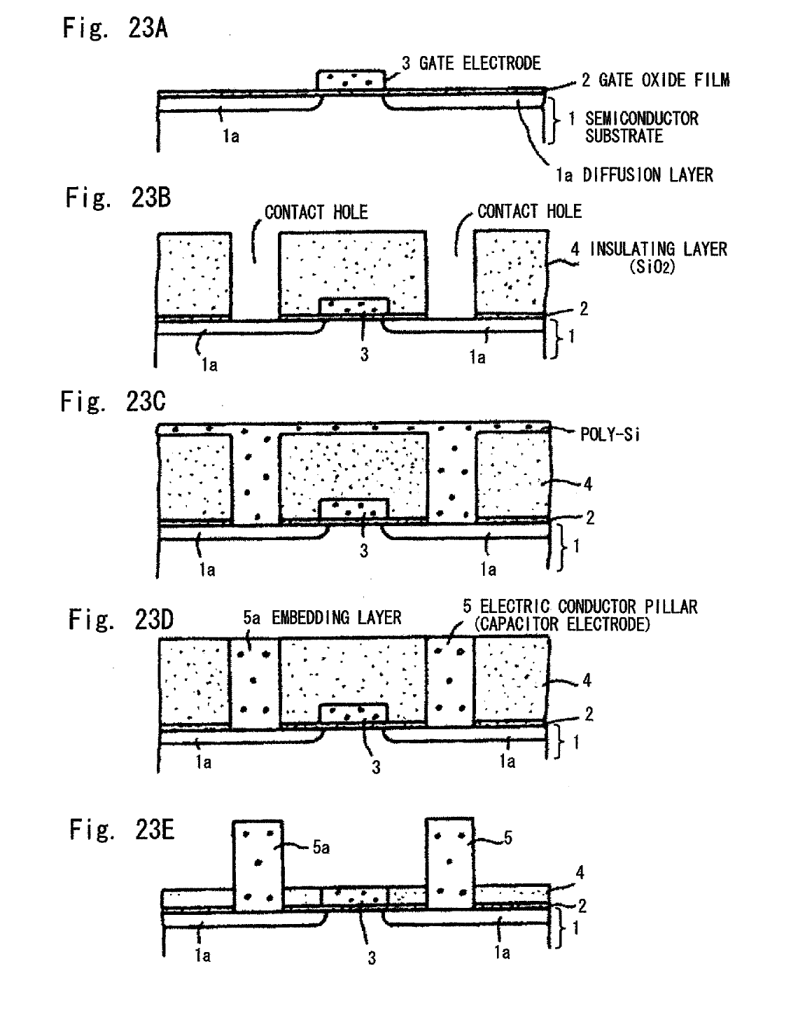

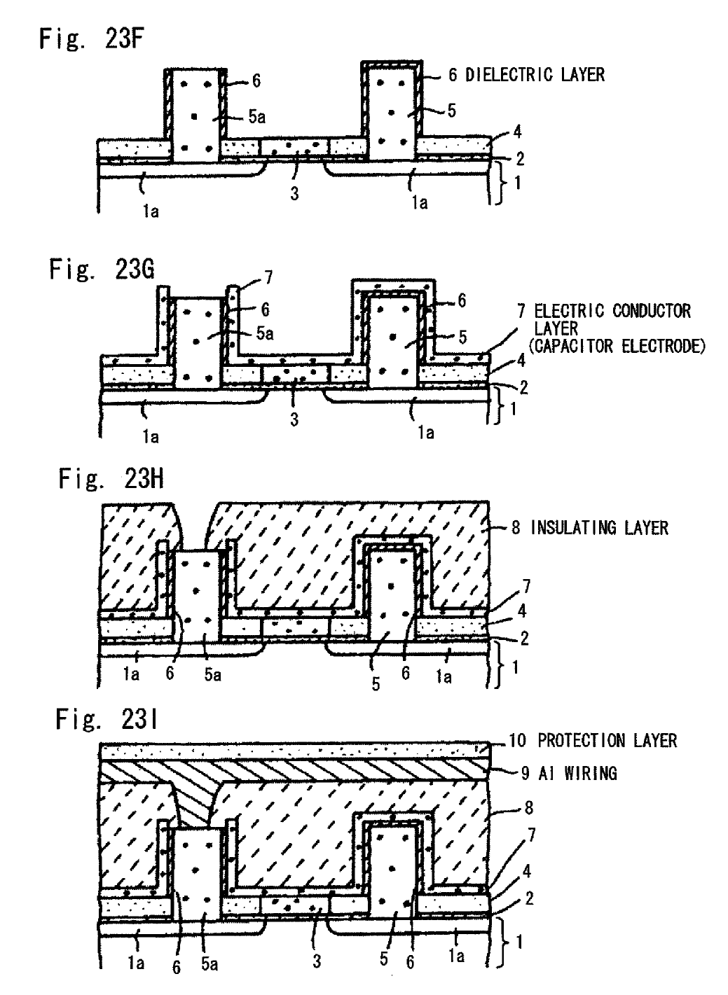

Note that in the fourth exemplary embodiment, the capacitive element insulating film 16 may remain on the side surface of the trench for wiring 152 as illustrated in FIG. 21. Even in such case, the metal body 17A may be embedded by damascene process in the trench for wiring 152 as illustrated in FIG. 22.

Since there is no electrode opposing the metal body 17A, even when the capacitive element insulating film 16 remains on the side surface of the trench for wiring 152, no parasitic capacitance is generated.

The first, second, third and fourth exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A manufacturing method of a semiconductor device embedded with a logic unit and a metal capacitive element, the manufacturing method comprising:
forming a first interlayer dielectric over a substrate;
forming a plurality of electric conductor pillars in the first interlayer dielectric;
making some of the plurality of electric conductor pillars to be lower electrodes of the metal capacitive element, and some of the remaining plurality of electric conductor pillars to be contact plugs of the logic unit;
smoothing an upper surface of the first interlayer dielectric, and then forming a damascene wiring part insulating film over the upper surface of the first interlayer dielectric;
removing the damascene wiring part insulating film above the lower electrode to form an opening part for capacitance;
forming an insulating film for capacitive element over the upper surface of the first interlayer dielectric;
removing the insulating film for capacitive element and the first interlayer dielectric above the contact plug to form a trench for wiring;
embedding metal bodies in the opening part for capacitance and the trench for wiring; and
making the metal body in the opening part for capacitance to be an upper electrode of the capacitive element and the metal body in the trench for wiring to be a logic wiring.

2. The manufacturing method according to claim 1, further comprising when forming the opening part for capacitance, etching down to a predetermined depth below an upper surface position of the electric conductor pillar except a part immediately above the electric conductor pillar to be the lower electrode,
wherein the metal body in the opening part for capacitance opposes the electric conductor pillar to be the lower electrode at an upper surface and a side surface of the electric conductor pillar.

3. A manufacturing method of a semiconductor device embedded with a logic unit and a metal capacitive element, the manufacturing method comprising:
forming a first interlayer dielectric over a substrate;
forming a plurality of electric conductor pillars in the first interlayer dielectric;
making some of the plurality of electric conductor pillars to be lower electrodes of the metal capacitive element, and some of the remaining plurality of electric conductor pillars to be contact plugs of the logic unit;
smoothing an upper surface of the first interlayer dielectric, and then forming a damascene wiring part insulating film over the upper surface of the first interlayer dielectric;
removing the damascene wiring part insulating film above the contact plug and the lower electrode to form a trench for wiring and an opening part for capacitance;
forming an insulating film for capacitive element over the damascene wiring part insulating film;
removing the insulating film for capacitive element above the contact plug;
embedding metal bodies in the opening part for capacitance and the trench for wiring; and
making the metal body in the opening part for capacitance to be an upper electrode of the capacitive element and the metal body in the trench for wiring to be a logic wiring.

4. The manufacturing method according to claim 1, further comprising:
disposing a plurality of electric conductor pillars as the lower electrodes; and
forming the metal body as the upper electrode to have an area to oppose the plurality of electric conductor pillars.

5. The manufacturing method according to claim 3, further comprising:
disposing a plurality of electric conductor pillars as the lower electrodes; and
forming the metal body as the upper electrode to have an area to oppose the plurality of electric conductor pillars.

6. The manufacturing method according to claim 1, wherein
an area of the electric conductor pillar to be the lower electrode is formed larger than an area of the electric conductor pillar to be the contact plug, and
the metal body as the upper electrode is formed to have an area to be able to oppose the electric conductor pillar to be the lower electrode.

7. The manufacturing method according to claim 3, wherein
an area of the electric conductor pillar to be the lower electrode is formed larger than an area of the electric conductor pillar to be the contact plug, and
the metal body as the upper electrode is formed to have an area to be able to oppose the electric conductor pillar to be the lower electrode.

8. A semiconductor device that is manufactured by the manufacturing method according to claim 1.

9. A semiconductor device that is manufactured by the manufacturing method according to claim 3.
